(19) United States
(12) Patent Application Publication
(10) Pub. No.: US 2007/0159162 A1
(43) Pub. Date: Jul. 12, 2007

(54) Method and apparatus for self-calibration in a mobile transceiver

(75) Inventors: Hyun-Il Kang, Yongin-si (KR); Jae-Kon Lee, Suwon-si (KR); Young-Hwan Lee, Seoul (KR); Hyeong-Seok Yu, Seoul (KR); Sang-Hyun Woo, Seoul (KR)

Correspondence Address: THE FARRELL LAW FIRM, P.C., 333 EARLE OVINGTON BOULEVARD, SUITE 701, UNIONDALE, NY, 11553, US

(73) Assignee: SAMSUNG ELECTRONICS CO., LTD., Suwon-si (KR)

(21) Appl. No.: 11/636,083

(22) Filed: Dec. 8, 2006

(30) Foreign Application Priority Data
Dec. 8, 2005 (KR) 2005-119864

(51) Int. Cl. G01R 31/28

(52) U.S. Cl. 324/158.1

(57) ABSTRACT

Disclosed is a method and an apparatus for self-calibrating a Direct Current (DC) offset and an imbalance between orthogonal signals, which may occur in a mobile transceiver. In the apparatus, a transmitter of a mobile terminal functions as a signal generator, and a receiver of the mobile terminal functions as a response characteristic detector. Further, a baseband processor applies test signals to the transmitter, receives the test signals returning from the receiver, and compensates the imbalance and DC offset for the transmitter side and the receiver side by using the test signals. The test signal is applied to only one of the I channel path and the Q channel path, and an RF band signal output from the transmission side by the test signal is used as an input signal to the reception side.

### PRIORITY

This application claims the benefit under 35 U.S.C. §119(a) of an application filed in the Korean Industrial Property Office on Dec. 8, 2005 and assigned Serial No. 2005-119864, the contents of which are incorporated herein by reference.

### BACKGROUND OF THE INVENTION

1. Field of the Invention

The present invention relates to a method and an apparatus for self-calibration in a mobile transceiver, and more particularly to a method and an apparatus for self-calibrating a Direct Current (DC) offset and imbalance between orthogonal signals.

2. Description of the Related Art

In general, basic causes of degrading performance of mobile transceivers include undesired or non-ideal characteristics, such as a DC offset and an I/Q imbalance.

The DC offset is caused by self mixing by a mixer in a wireless receiver. The DC offset occurs when a signal of a Local Oscillator (LO) returns after leaking toward an antenna or when a Radio Frequency (RF) modulation signal input through the antenna is leaked to the LO. The DC offset value generated in this way may saturate a Base band (BB) circuit.

The I/Q imbalance is caused by self-defects of an oscillator including a phase retarder and a line interconnecting the oscillator and a mixer. The I/Q imbalance is caused when the phase difference between the in-phase channel signal (I channel signal) and the quadrature-phase channel signal (Q channel signal) generated in an oscillator of a wireless transmitter is not 90 degrees. The I/Q imbalance can be reduced by designing mixers of the I channel demodulator and the Q channel demodulator to be symmetric to each other. However, designing the mixers to be symmetric to each other requires an increase in the volume and current consumption of the mixers. Such I/Q imbalances cause decreases in the Signal to Noise Ratio (SNR), which increases the Bit Error Rate (BER), thereby degrading the performance of the wireless transceiver.

Therefore, in order to improve the performance of a wireless transceiver, it is necessary to arrange a solution for estimating the DC offset and the I/Q imbalance and calibrating the estimated the DC offset and the I/Q imbalance.

FIG. 1 illustrates a representative example of a process for self-estimating and self-calibrating a DC offset and an I/Q imbalance which occur in a conventional wireless transceiver. The example shown in FIG. 1 is disclosed in a Patent Cooperation Treaty (PCT) application No. 2004/023667, entitled “Direct Conversion Transceiver Enabling Digital Calibration,” and a paper by James K. Cavers, entitled “New Methods for Adaptation of Quadrature Modulators and Demodulators in Amplifier Linearization Circuits.”

For convenience of description, the estimation path is not distinguished into an I channel path and a Q channel path. However, the same application is possible even when the estimation path is distinguished into an I channel path and a Q channel path.

The solution proposed in FIG. 1 calibrates both the I/Q imbalance and the DC offset generated at a transmission (TX) side and a reception (RX) side. To this end, calibration for the TX side is first performed, and calibration for the RX side is then performed. In other words, for the calibration for the RX side, the calibration for the TX side must precede it. The calibration for the TX side corresponds to imbalance calibration between I channel and Q channel (TX IQ calibration). The calibration for the RX side includes calibration for the DC offset as well as the imbalance calibration between the I channel and the Q channel.

In the estimator shown in FIG. 1, a discrete detector is used. The discrete detector converts an envelope signal output from a drive amplifier of the TX side into a Baseband (BB) signal and takes a discrete Fourier series for a complex envelope waveform of the BB signal. Based on the discrete Fourier series, the discrete detector estimates the gain imbalance, the phase imbalance, and the DC offset of each of the I channel and the Q channel at the TX side.

However, in the estimation as described above, it is necessary to consider the non-ideal factors, which include a differential gain and a Direct Current (DC) value. In the above-mentioned paper and patent application, the non-ideality factors are estimated.

The TX and RX gain imbalance, phase imbalance, and DC offsets of the I channel and Q channel obtained through the estimation may be incorrect.

Further, as noted from FIG. 1, many separate diodes, registers, capacitors, and switches are necessary in order to construct the discrete detector. Also, a great amount of time is required for self-calibration of the DC offset and the imbalance between the orthogonal signals.

### SUMMARY OF THE INVENTION

Accordingly, the present invention has been made to solve at least the above-mentioned problems occurring in the prior art, and an object of the present invention is to provide an apparatus and a method for self-estimating and self-calibrating the DC offset characteristics and the imbalance characteristics.

It is another object of the present invention to provide an apparatus and a method for estimating and calibrating the DC offset characteristics and the imbalance characteristics in a single path connected between a transmission side and a reception side.

It is another object of the present invention to provide an apparatus and a method for estimating the DC offset characteristics of a reception side based on a test signal that is received by the reception side by applying a test signal through an uncalibrated transmission side.

It is another object of the present invention to provide an apparatus and a method for estimating the imbalance characteristics of a reception side based on a test signal that is received by the reception side by applying a test signal through an uncalibrated transmission side.

It is another object of the present invention to provide an apparatus and a method for estimating the imbalance characteristics of an uncalibrated transmission side based on a test signal that is received by an already calibrated reception side by applying a test signal through the uncalibrated transmission side.

It is another object of the present invention to provide an apparatus and a method for estimating the DC offset characteristics and the imbalance characteristics of a reception side by applying a test signal to only one of the I channel path and the Q channel path of the transmission side.

It is another object of the present invention to provide an apparatus and a method for estimating the DC offset characteristics and the imbalance characteristics of a transmission side by applying a test signal to only one of the I channel path and the Q channel path of the transmission side.

In order to accomplish these and other objects, there is provided a method for self-calibration in a transceiver having a test path for applying a Radio Frequency (RF) band signal from a transmission side to a reception side, the method comprising sequentially generating a first in-phase channel test signal and a second in-phase channel test signal in an analog baseband of a transmission side at a predetermined time interval; converting the first in-phase channel test signal and the second in-phase channel test signal of the analog baseband to a first RF band signal and a second RF band signal according to an order in which the first in-phase channel test signal and the second in-phase channel test signal are generated, and then applying the first RF band signal and the second RF band signal to the reception side through the test path; outputting first and second in-phase channel test signals and first and second quadrature-phase channel test signals by converting the first RF band signal and the second RF band signal to analog baseband signals by means of a first carrier for an in-phase channel and a second carrier for a quadrature-phase channel, respectively; calibrating a DC offset characteristic for in-phase channel reception signals in the analog baseband of the reception side by using an average value of the first and second in-phase channel test signals; and calibrating a DC offset characteristic for quardrature-phase channel reception signals in the analog baseband of the reception side by using an average value of the first and second quardrature-phase channel test signals.

In accordance with another aspect of the present invention, there is provided an apparatus for self-calibration in a transceiver having a test path for applying a Radio Frequency (RF) band signal from a transmission side to a reception side, wherein the apparatus sequentially generates a first in-phase channel test signal and a second in-phase channel test signal in an analog baseband of a transmission side at a predetermined time interval; converts the first in-phase channel test signal and the second in-phase channel test signal of the analog baseband to a first RF band signal and a second RF band signal according to an order in which the first in-phase channel test signal and the second in-phase channel test signal are generated, and then applies the first RF band signal and the second RF band signal to the reception side through the test path; outputs first and second in-phase channel test signals and first and second quadrature-phase channel test signals by converting the first RF band signal and the second RF band signal to analog baseband signals by means of a first carrier for an in-phase channel and a second carrier for a quadrature-phase channel, respectively; calibrates a DC offset characteristic for in-phase channel reception signals in the analog baseband of the reception side by using an average value of the first and second in-phase channel test signals; and calibrates a DC offset characteristic for quardrature-phase channel reception signals in the analog baseband of the reception side by using an average value of the first and second quardrature-phase channel test signals.

### BRIEF DESCRIPTION OF THE DRAWINGS

The above and other objects, features and advantages of the present invention will be more apparent from the following detailed description taken in conjunction with the accompanying drawings, in which:

FIG. 1 illustrates a representative example of a process for self-estimating and self-calibrating a DC offset and an I/Q imbalance which occur in a conventional wireless transceiver;

FIG. 2 is a block diagram illustrating a structure of a mobile terminal according to the present invention;

FIG. 3 is a flowchart of a process for self-calibration by a DSP according to the present invention; and

FIG. 4 is a graph for illustrating a comparison between a test signal transmitted to the transmission side and a test signal received by the reception side.

### DETAILED DESCRIPTION OF THE PREFERRED EMBODIMENT

Hereinafter, preferred embodiments of the present invention will be described with reference to the accompanying drawings. In the following description, a detailed description of known functions and configurations incorporated herein will be omitted when it may make the subject matter of the present invention rather unclear.

Before description of preferred embodiments, terms used herein are defined as follows:

I_{TX}: an in-phase channel test signal that is applied through the I channel path of the TX side in order to calibrate the imbalance characteristics between the I channel path and the Q channel path and the DC offset characteristic occurring in the I channel path of the RX side;

I_{Rx}: an in-phase channel test signal, which is output as a baseband signal by LO_{II} from a mixer in the I channel path of the RX side, wherein the baseband signal is obtained from an RF RX signal input to the mixer in the I channel path of the RX side, the RF RX signal is obtained from an RF TX signal output from a mixer in the I channel path of the TX side, and the RF TX signal is obtained from the I_{RX} input through the I channel to the mixer of the TX side;

Q_{RX}: a quadrature-phase channel test signal, which is output as a baseband signal by LO_{QQ} from a mixer in the Q channel path of the RX side, wherein the baseband signal is obtained from an RF RX signal input to the mixer in the Q channel path of the RX side, the RF RX signal is obtained from an RF TX signal output from a mixer in the I channel path of the TX side, and the RF TX signal is obtained from the ITx input through the I channel to the mixer of the TX side;

LO_{II}: a carrier frequency which is used in order to convert a Radio Frequency (RF) band signal to a baseband signal in the I channel path of the RX side;

LO_{QQ}: a carrier frequency which is used in order to convert an RF band signal to a baseband signal in the Q channel path of the RX side;

LO_{Q}: a carrier frequency which is used in order to convert a baseband signal to an RF band signal in the I channel path of the TX side; and

LO_{Q}: a carrier frequency which is used in order to convert a baseband signal to an RF band signal in the Q channel path of the TX side.

A method for estimating and calibrating imbalance characteristics and DC offset characteristics according to the present invention by a mobile terminal, in which a test signal generated by a transmitter side is provided to a receiver side and is then used to estimate and calibrate the imbalance characteristics and DC offset characteristics, will be described in detail.

The test signal has a predetermined shape, which includes a shape of a simple wave, such as a sine wave or a cosine wave.

Each test signal for estimation of the DC offset of the RX side and the imbalance of the RX side and the TX side is applied to only one channel path of the I channel path and the Q channel path. The following embodiments are based on an assumption that a test signal for estimating the DC offset and the imbalance of the RX side is applied to only the I channel path and a test signal for estimating the imbalance of the TX side is applied to only the Q channel path. Of course, it is also possible to apply a test signal for estimating the DC offset and the imbalance of the RX side to only the Q channel path and apply a test signal for estimating the imbalance of the TX side to only the I channel path.

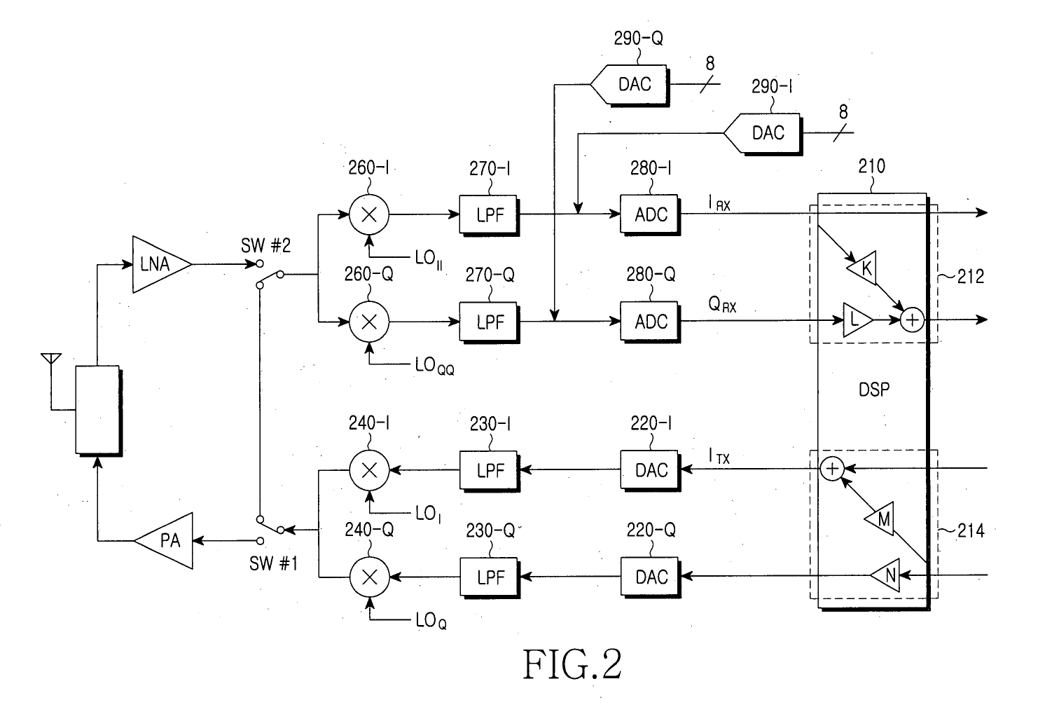

FIG. 2 is a block diagram which illustrates a structure of a mobile terminal according to the present invention. Although the discussion in the present embodiment is based on a mobile terminal, the present invention can be applied to all apparatuses and systems which can perform wireless communication.

A. Calibration of DC Offset of the RX Side

Referring to FIG. 2, the TX side includes Digital-to-Analog Converters (DACs) 220-I and 220-Q and Low Pass Filters (LPFs) 230-I and 230-Q, and mixers 240-I and 240-Q, which are arranged along the I channel path and the Q channel path of the TX side, respectively. Further, the RX side includes mixers 260-I and 260-Q, LPFs 270-I and 270-Q, and Analog-to-Digital Converters (ADCs) 280-I and 280-Q, which are arranged along the I channel path and the Q channel path of the RX side, respectively.

The Digital Signal Processor (DSP) 210 generates predefined test signals and applies the generated test signals to the I channel path of the TX side, in order to estimate the DC offset characteristics. Further, by using a baseband test signal received through the RX side, the DSP 210 estimates the DC offset characteristics. Based on the estimated DC offset characteristics, the DSP calibrates the DC offset of the RX side.

First, the DSP 210 applies test signals I_{TX} to the DAC 220-I, in order to estimate the DC offset characteristics of the RX side. Specifically, the DSP 210 applies two different baseband test signals I_{TX#1} and I_{TX#2} at a predetermined time interval, in order to estimate the DC offset characteristics of the RX side. However, no test signal is applied to the DAC 220-Q at all. Therefore, the operations of the DAC 220-Q, the LPF 230-Q, and the mixer 240-Q in the Q channel path of the TX side will not be considered herein.

In the discussion below, the operation by the I_{TX#1} and the operation by the I_{TX#2} are discriminated from each other. First, the operation when the I_{TX#1} is applied as a test signal will be described hereinafter. One example of I_{TX#1} can be defined by Equation (1)
I_{TX#1}(t)=cos ω̅₀t (1)

The DAC 220-I converts the applied I_{TX#1} to an analog signal and then inputs the converted analog signal to the LPF 230-I.

The analog signal I_{TX#1} is filtered by the LPF 230-I and is then converted to an RF band signal by the mixer 240-I. The carrier in the mixer 240-I corresponds to LO_{I} and the carrier in the mixer 240-Q corresponds to LO_{Q}. LO_{I} and LO_{Q} can be defined by Equation (2)
LO_{I}=cos ω̅t
LO_{Q}=α1 sin( ω̅t+φ1) (2)

In Equation (2), α1 denotes the gain imbalance characteristic between the I channel path and the Q channel path of the TX side, and φ2 denotes the phase imbalance characteristic between the I channel path and the Q channel path of the TX side.

The RF TX signal TX_{output#}of the RF band converted by the mixer 240-I can be defined by Equation (3)

$$\begin{matrix}{TX}_{output \#1} ( t ) = {I}_{TX \#1} ( t ) \cdot A \cdot cos {ϖ}_{c} ϖ t \\ = A \cdot cos ( ϖ - {ϖ}_{0} ) + A \cdot cos ( ϖ + {ϖ}_{0} ) t\end{matrix} \qquad ( 3 )$$

The RF TX signal TX_{output#1} is transferred to the RX side through a test path formed by the first switch SW#1 and the second switch SW#2. The RF band signal RX_{input#1} transferred to the RX side can be defined by Equation (4)
RX_{input#1}(t)=A·cos( ω̅_{c}t− ω̅₀t+θ)+A·cos( ω̅_{c}t+ ω̅₀t+θ) (4)

The RF band signal RX_{input#1} transferred to the RX side through the second switch SW#2 is converted to a baseband signal by the mixer 260-I in the I channel path. The mixer 260-I uses a carrier LO_{II} which can be defined by Equation (5)
LO_{II}=cos ω̅t (5)

Further, the RF band signal RX_{input#1} transferred to the RX side through the second switch SW#2 is converted to a baseband signal by the mixer 260-Q in the Q channel path. The mixer 260-Q uses a carrier LO_{QQ}, which can be defined by Equation (6)
LO_{QQ}=α2 sin( ω̅t+φ2) (6)

In Equation (6), α2 denotes the gain imbalance characteristic between the I channel path and the Q channel path of the RX side, and φ2 denotes the phase imbalance characteristic between the I channel path and the Q channel path of the RX side.

The baseband signal output from the mixer 260-I is filtered by the LPF 270-I in the I channel path and is then transferred to the ADC 280-I, by which it is converted to a digital signal. The digital signal converted by the ADC 280-I corresponds to I_{RX#1}. The baseband signal output from the mixer 260-Q is filtered by the LPF 270-Q in the Q channel path and is then transferred to the ADC 280-Q, by which it is converted to a digital signal. The digital signal converted by the ADC 280-Q corresponds to Q_{RX#1}. The I_{RX#1} and the Q_{RX#1} are defined by Equation (7)

$$\begin{matrix}{I}_{RX \#1} ( t ) = \frac{A}{2} \cdot cos ( {ϖ}_{0} t - θ ) + \frac{A}{2} \cdot cos ( {ϖ}_{0} t + θ ) + Δ I \\ {Q}_{RX \#1} ( t ) = \frac{α 2 \cdot A}{2} \cdot sin ( {ϖ}_{0} t - θ + ϕ2 ) - \\ \frac{α2 \cdot A}{2} \cdot sin ( {ϖ}_{0} t + θ - ϕ2 ) + Δ Q\end{matrix} \qquad ( 7 )$$

The I_{RX#1} and the Q_{RX#1} are provided to the DSP 210.

Next, the operation when the I_{TX#2} is applied as a test signal will be described hereinafter. One example of I_{TX#2} can be defined by Equation (8) below.
I_{TX#2}(t)=−cos ω̅₀t (8)

The I_{TX#1} and I_{TX#2} are signals having a phase difference of 180 degrees. Any pair of signals having simple waveforms with a phase difference of 180 degrees can be used as the I_{TX#1} and I_{TX#2}.

The DAC 220-I converts the applied I_{TX#2} to an analog signal and then inputs the converted analog signal to the LPF 230-I.

The analog signal I_{TX#2} is filtered by the LPF 230-I and is then converted to an RF band signal by the mixer 240-I. The carrier in the mixer 240-I corresponds to the LO_{I} defined by Equation (2).

The RF TX signal TX_{output#2} of the RF band converted by the mixer 240-I can be defined by Equation (9)

$$\begin{matrix}{TX}_{output \#2} ( t ) = {I}_{TX \#2} ( t ) \cdot A \cdot cos {ϖ}_{c} ϖ t \\ = - A \cdot cos ( ϖ - {ϖ}_{0} ) - A \cdot cos ( ϖ + {ϖ}_{0} ) t\end{matrix} \qquad ( 9 )$$

The RF TX signal TX_{output#2} is transferred to the RX side through a test path formed by the first switch SW#1 and the second switch SW#2. The RF band signal RX_{input#2} transferred to the RX side can be defined by equation (10) below.
RX_{input#2}(t)=−A·cos( ω̅_{c}t− ω̅₀t+θ)−A·cos( ω̅_{c}t+ ω̅₀t+θ) (10)

The RF band signal RX_{input#2} transferred to the RX side through the second switch SW#2 is converted to a baseband signal by the mixer 260-I in the I channel path. The mixer 260-I uses the carrier LO_{II} defined by Equation (5).

Further, the RF band signal RX_{input#2} transferred to the RX side through the second switch SW#2 is converted to a baseband signal by the mixer 260-Q in the Q channel path. The mixer 260-Q uses the carrier LO_{QQ} defined by Equation (6).

The baseband signal output from the mixer 260-I is filtered by the LPF 270-I in the I channel path and is then transferred to the ADC 280-I, by which it is converted to a digital signal. The digital signal converted by the ADC 280-I corresponds to I_{RX#2}. The baseband signal output from the mixer 260-Q is filtered by the LPF 270-Q in the Q channel path and is then transferred to the ADC 280-Q, by which it is converted to a digital signal. The digital signal converted by the ADC 280-Q corresponds to Q_{RX#2}. The IRX#2 and the Q_{RX#2} are defined by Equation (11)

$$\begin{matrix}{I}_{RX \#2} ( t ) = - \frac{A}{2} \cdot cos ( {ϖ}_{0} t - θ ) - \frac{A}{2} \cdot cos ( {ϖ}_{0} t + θ ) + Δ I \\ {Q}_{RX \#2} ( t ) = - \frac{α 2 \cdot A}{2} \cdot sin ( {ϖ}_{0} t - θ + ϕ2 ) + \\ \frac{α2 \cdot A}{2} \cdot sin ( {ϖ}_{0} t + θ - ϕ2 ) + Δ Q\end{matrix} \qquad ( 11 )$$

The I_{RX#2} and the Q_{RX#2} are provided to the DSP 210.

The DSP 210 estimates the DC offset characteristic ΔI of the I channel path of the RX side by using I_{RX#1 and I}_{RX#2}, and estimates the DC offset characteristic ΔQ of the Q channel path by using Q_{RX#1} and Q2_{RX#2}. The ΔI and ΔQ can be estimated by using Equation (12)

$$Δ I = \frac{{I}_{RX \#1} + {I}_{RX \#2}}{2} \\ Δ Q = \frac{{Q}_{RX \#1} + {Q}_{RX \#2}}{2} \qquad ( 12 )$$

As noted from Equation (12), ΔI can be estimated as a mean value of test signals I_{RX#1} and I_{RX#2} which are consecutively received through the I channel path of the RX side, and ΔQ can be estimated as a mean value of test signals Q_{RX#1} and Q_{RX#2} which are consecutively received through the Q channel path of the RX side.

The DSP 210 determines a calibration value for calibrating ΔI and a calibration value for calibrating ΔQ.

The calibration value for calibrating ΔI is transferred to the DAC 290-I and is converted to an analog signal by the DAC 290-I, and the calibration value for calibrating ΔQ is transferred to the DAC 290-Q and is converted to an analog signal by the DAC 290-Q.

The DC offset characteristic for the received signals in an analog baseband in the I channel of the RX side is counterbalanced by the calibration value for calibrating the converted analog signal ΔI. The analog baseband in the I channel of the RX side corresponds to the section from the output port of the mixer 260-I to the input port or output port of the LPF 270-I.

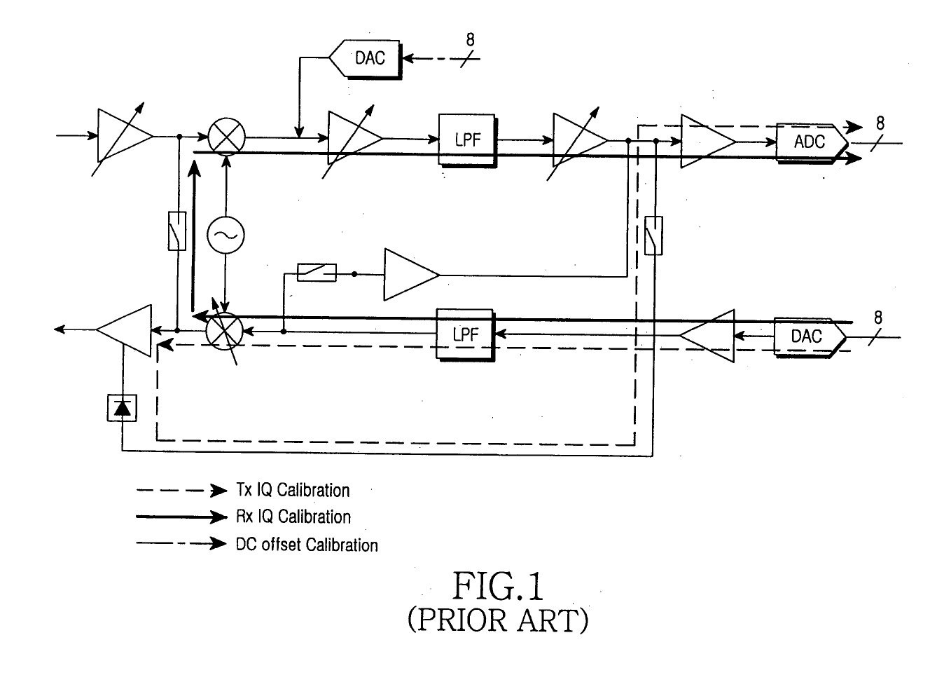

The DC offset characteristic for the received signals in an analog baseband in the Q channel of the RX side is counterbalanced by the calibration value for calibrating the converted analog signal ΔQ. The analog baseband in the Q channel of the RX side corresponds to the section from the output port of the mixer 260-Q to the input port of the LPF 270-Q. FIG. 1 is based on an assumption that the analog baseband corresponds to the section from the output port of the mixer 260-Q to the output port of the LPF 270-Q.

B. Calibration of Imbalance of the RX Side

The DSP 210 generates predefined test signals and applies the generated test signals to the I channel path of the TX side, in order to estimate the DC offset characteristics. Further, by using a baseband test signal received through the RX side, the DSP 210 estimates the DC offset characteristics. Based on the estimated DC offset characteristics, the DSP calibrates the DC offset of the RX side.

The DSP 210 applies test signals I_{TX} to the DAC 220-I, in order to estimate the DC offset characteristics of the RX side. Specifically, the DSP 210 applies two different baseband test signals I_{TX#1} and I_{TX#3} at a predetermined time interval, in order to estimate the DC offset characteristics of the RX side. However, no test signal is applied to the DAC 220-Q at all. Therefore, the operations of the DAC 220-Q, the LPF 230-Q, and the mixer 240-Q in the Q channel path of the TX side are not taken into consideration.

In the discussion below, the operation by the I_{TX#1} and the operation by the I_{TX#3} are discriminated.

First, the operation when the I_{TX#1} is applied as a test signal will be described. The DAC 220-I converts the applied I_{TX#1} to an analog signal and then inputs the converted analog signal to the LPF 230-I.

The analog signal I_{TX#1} is filtered by the LPF 230-I and is then converted to an RF band signal by the mixer 240-I. The carrier in the mixer 240-I corresponds to LO_{I} and the carrier in the mixer 240-Q corresponds to LO_{Q}. LO_{I} and LO_{Q} can be defined by Equation (2) as described above.

The RF TX signal TX_{output#1} of the RF band converted by the mixer 240-I can be defined by Equation (3) as described above.

The RF TX signal TX_{output#1} is transferred to the RX side through a test path formed by the first switch SW#1 and the second switch SW#2. The RF band signal RX_{input#1} transferred to the RX side can be defined by equation (4) as described above.

The RF band signal RX_{input#1} transferred to the RX side through the second switch SW#2 is converted to a baseband signal by the mixer 260-I in the I channel path. The mixer 260-I uses a carrier LO_{II} which is defined by Equation (5) as described above.

Further, the RF band signal RX_{input#1} transferred to the RX side through the second switch SW#2 is converted to a baseband signal by the mixer 260-Q in the Q channel path. The mixer 260-Q uses a carrier LO_{QQ}, which is defined by Equation (6) as described above.

The baseband signal output from the mixer 260-I is filtered by the LPF 270-I in the I channel path and is then transferred to the ADC 280-I, by which it is converted to a digital signal. The digital signal converted by the ADC 280-I corresponds to I_{RX#1}. The baseband signal output from the mixer 260-Q is filtered by the LPF 270-Q in the Q channel path and is then transferred to the ADC 280-Q, by which it is converted to a digital signal. The digital signal converted by the ADC 280-Q corresponds to Q_{RX#1}. On the assumption that the DC offset has been already calibrated, the I_{RX#1} and the Q_{RX#1} are defined by Equation (13)

$$\begin{matrix}{I}_{RX \#1} ( t ) = \frac{A}{2} \cdot cos ( {ϖ}_{0} t - θ ) + \frac{A}{2} \cdot cos ( {ϖ}_{0} t + θ ) \\ {Q}_{RX \#1} ( t ) = \frac{α 2 \cdot A}{2} \cdot sin ( {ϖ}_{0} t - θ + ϕ2 ) - \\ \frac{α2 \cdot A}{2} \cdot sin ( {ϖ}_{0} t + θ - ϕ2 )\end{matrix} \qquad ( 13 )$$

From comparison between Equation (13) and Equation (5), it is noted that Equation (13) does not include ΔI and ΔQ, which are elements due to the DC offset characteristics.

The I_{RX#1} and the Q_{RX#1} are provided to the DSP 210.

Next, the operation when the I_{TX#3} is applied as a test signal will be described. One example of I_{TX#3} can be defined by Equation (14)
I_{TX#3}(t)=sin ω̅₀t (14)

The I_{TX#1} and I_{TX#3} are signals having a phase difference of 90 degrees. Any pair of signals having simple waveforms with a phase difference of 90 degrees can be used as the I_{TX#1} and I_{TX#3}.

The DAC 220-I converts the applied I_{TX#3} to an analog signal and then inputs the converted analog signal to the LPF 230-I.

The analog signal I_{TX#3} is filtered by the LPF 230-I and is then converted to an RF band signal by the mixer 240-I. The carrier in the mixer 240-I corresponds to the LO_{I} defined by Equation (2).

The RF TX signal TX_{output#3} of the RF band converted by the mixer 240-I can be defined by Equation (15)

$$\begin{matrix}{TX}_{output \#3} ( t ) = {I}_{TX \#3} ( t ) \cdot A \cdot cos {ϖ}_{c} t \\ = - A \cdot sin ( ϖ - {ϖ}_{0} ) + A \cdot sin ( ϖ + {ϖ}_{0} ) t\end{matrix} \qquad ( 15 )$$

The RF TX signal TX_{output#3} is transferred to the RX side through a test path formed by the first switch SW#1 and the second switch SW#2. The RF band signal RX_{input#3} transferred to the RX side can be defined by Equation (16) below.
RX_{input#3}(t)=−A·sin( ω̅_{c}t− ω̅₀t+θ)+Asin( ω̅_{c}t+ ω̅₀t+θ) (16)

The RF band signal RX_{input#3} transferred to the RX side through the second switch SW#2 is converted to a baseband signal by the mixer 260-I in the I channel path. The mixer 260-I uses the carrier LO_{II} defined by Equation (5).

Further, the RF band signal RX_{input#3} transferred to the RX side through the second switch SW#2 is converted to a baseband signal by the mixer 260-Q in the Q channel path. The mixer 260-Q uses the carrier LO_{QQ} defined by Equation (6).

The baseband signal output from the mixer 260-I is filtered by the LPF 270-I in the I channel path and is then transferred to the ADC 280-I, by which it is converted to a digital signal. The digital signal converted by the ADC 280-I corresponds to I_{RX#3}. The baseband signal output from the mixer 260-Q is filtered by the LPF 270-Q in the Q channel path and is then transferred to the ADC 280-Q, by which it is converted to a digital signal. The digital signal converted by the ADC 280-Q corresponds to Q_{RX#3}.

The I_{RX#3} and the Q_{RX#3} are defined by Equation (17)

$$\begin{matrix}{I}_{RX \#3} ( t ) = \frac{A}{2} \cdot sin ( {ϖ}_{0} t - θ ) - \frac{A}{2} \cdot sin ( {ϖ}_{0} t + θ ) \\ {Q}_{RX \#3} ( t ) = - \frac{α 2 \cdot A}{2} \cdot cos ( {ϖ}_{0} t - θ + ϕ2 ) + \\ \frac{α2 \cdot A}{2} \cdot cos ( {ϖ}_{0} t + θ - ϕ2 )\end{matrix} \qquad ( 17 )$$

The I_{RX#3} and the Q_{RX#3} are provided to the DSP 210.

The DSP 210 estimates the imbalance characteristics α2 and φ2 between the I channel path and the Q channel path of the RX side by using the I_{RX#1} and Q_{RX#1}, and the I_{RX#3} and Q_{RX#3}. The α2 and φ2 can be estimated by using Equation (18)

$$α2 = \sqrt{\frac{u {2}^{2} + u {4}^{2}}{u {1}^{2} + u {3}^{2}}} \\ ϕ2 = {tan}^{- 1} ( \frac{2 \cdot u 1 \cdot u 3}{u {1}^{2} - u {3}^{2}} ) \qquad ( 18 )$$

In Equation (18), α2 denotes the gain imbalance characteristics between the I channel path and the Q channel path of the RX side, and φ2 denotes the phase imbalance characteristics between the I channel path and the Q channel path of the RX side.

Further, u1, u2, u3, and u4 used in Equation (18) can be defined by Equation (19)

$$\begin{matrix}u 1 = Re ( {S}_{RX \#1} ( t ) \cdot {ⅇ}^{j {w}_{0} t} ) \\ = {I}_{RX \#1} ( t ) \cdot cos {ϖ}_{0} t - {Q}_{RX \#1} ( t ) \cdot sin {ϖ}_{0} t = \frac{A}{2} cos θ\end{matrix} \\ \begin{matrix}u 2 = Im ( {S}_{RX \#1} ( t ) \cdot {ⅇ}^{{jϖ}_{0} t} ) \\ = {I}_{RX \#1} ( t ) \cdot sin {ϖ}_{0} t + {Q}_{RX \#1} ( t ) \cdot cos {ϖ}_{0} t \\ = - \frac{α2 \cdot A}{2} sin ( θ - ϕ2 )\end{matrix} \\ \begin{matrix}u 3 = Re ( {S}_{RX \#3} ( t ) \cdot {ⅇ}^{j {w}_{0} t} ) \\ = {I}_{RX \#3} ( t ) \cdot cos {ϖ}_{0} t - {Q}_{RX \#3} ( t ) \cdot sin {ϖ}_{0} t \\ = \frac{A}{2} sin θ\end{matrix} \\ \begin{matrix}u 4 = Im ( {S}_{RX \#3} ( t ) \cdot {ⅇ}^{{jϖ}_{0} t} ) \\ = {I}_{RX \#3} ( t ) \cdot sin {ϖ}_{0} t - {Q}_{RX \#3} ( t ) \cdot cos {ϖ}_{0} t \\ = \frac{α2 \cdot A}{2} cos ( θ - ϕ2 )\end{matrix} \qquad ( 19 )$$

In Equation (19), S_{RX#1}(t) is equal to I_{RX#1}(t)+jQ_{RX#1}(t), and S_{RX#3}(t) is equal to I_{RX#3}(t)+jQ_{RX#3}(t).

The DSP 210 calculates calibration values K and L for calibrating the imbalance characteristics of the RX side by using the estimated α2 and φ2. K and L can be defined by Equation (20)

$$K = - tan ϕ2 \\ L = \frac{1}{α2 cos ϕ2} \qquad ( 20 )$$

Based on the calculated K and L, a first calibrator 212 within the DSP 210 calibrates the imbalance characteristics between the I channel reception signal and the Q channel reception signal. The calibration of the imbalance characteristics is to make the I channel reception signal and the Q channel reception signal have a desired phase difference (90 degrees) between them. Therefore, it will do if the calibration of the imbalance characteristic is performed for only one of the I channel reception signal and the Q channel reception signal. FIG. 2 is based on an assumption that calibration is performed on the Q channel reception signal.

The first calibrator 212 adds the Q channel reception signal having been multiplied by the calibration value L and the I channel reception signal having been multiplied by the calibration value K, thereby outputting a new Q channel reception signal for which the imbalance characteristic has been calibrated. The calibration of the imbalance characteristic by the first calibrator 212 can be defined by Equation (21)
Q_{TX}_{_{—}}_{calibration}=K×I_{RX}+L×Q_{RX} (21)

In Equation (21), Q_{TX}_{_{—}}_{calibration} denotes the Q channel reception signal for which the imbalance characteristic has been calibrated, I_{RX} denotes the I channel reception signal, and Q_{RX} denotes the Q channel reception signal.

C. Calibration of Imbalance of the TX Side

The DSP 210 applies test signals to the I channel path and the Q channel path of the TX side in order to estimate the imbalance characteristic between the I channel path and the Q channel path of the TX side. The test signals include I_{TX} and Q_{TX}, which can be defined by Equation (22)
I_{TX}=0
Q_{TX}=1 (22)

The DSP 210 applies I_{TX} and Q_{TX} to the TX side, and then receives I_{RX} and Q_{RX} through the I channel path and the Q channel path of the RX side. A process of applying I_{TX} and Q_{TX} to the TX side and then receiving I_{RX} and Q_{RX} is the same as the process described above, so detailed description thereof will be omitted here.

The DSP 210 estimates the imbalance characteristics α1 and φ1 between the I channel path and the Q channel path of the TX side based on I_{RX} and Q_{RX}. α1 and φ1 can be estimated by using Equation (23)

$$α1 = \sqrt{{I}_{RX}^{2} + {Q}_{RX}^{2}} \\ ϕ1 = {tan}^{- 1} \frac{{I}_{RX}}{{Q}_{RX}} \qquad ( 23 )$$

In Equation (23), α1 denotes the gain imbalance characteristic between the I channel path and the Q channel path of the TX side, and φ1 denotes the phase imbalance characteristic between the I channel path and the Q channel path of the TX side.

The DSP 210 calculates calibration values M and N for calibrating the imbalance characteristics of the RX side by using the estimated α1 and φ1. The values M and N can be calculated by using Equation (24)

$$M = - tan ϕ1 \\ N = \frac{1}{α1 cos ϕ1} \qquad ( 24 )$$

A second calibrator 214 within the DSP 210 calibrates the imbalance characteristics between the I channel transmission signal and the Q channel transmission signal by using the calculated M and N. The calibration of the imbalance characteristics is to make the I channel transmission signal and the Q channel transmission signal have a desired phase difference (90 degrees) between them.

The second calibrator 214 adds the Q channel transmission signal having been multiplied by the calibration value M and the I channel transmission signal, thereby outputting a new I channel transmission signal for which the imbalance characteristics have been calibrated. Further, the second calibrator 214 multiplies a calibration value N by the Q channel transmission signal, thereby outputting a new Q channel transmission signal for which the imbalance characteristics have been calibrated.

Process

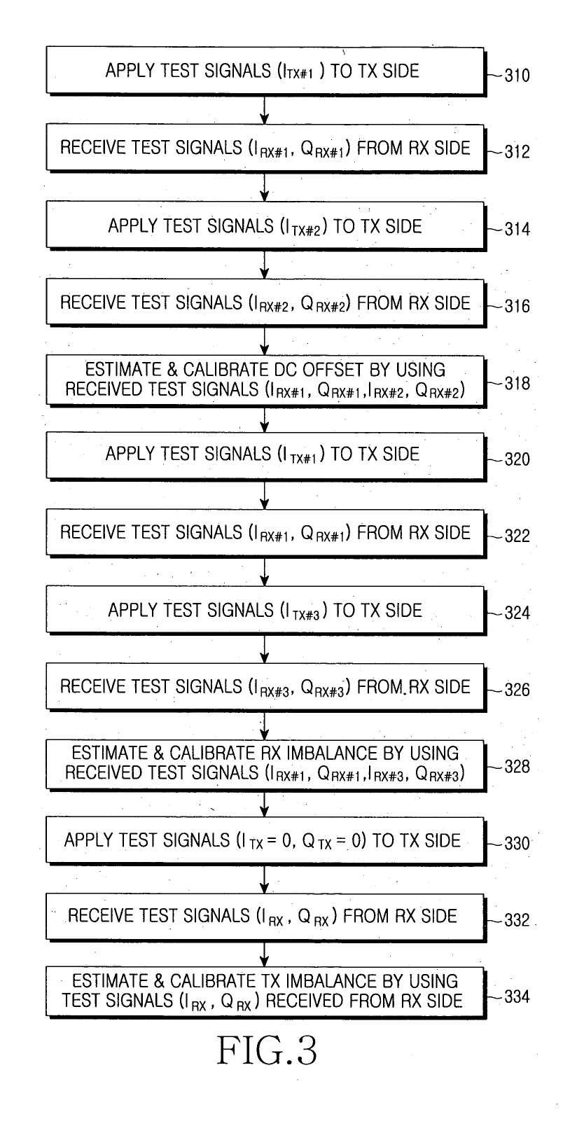

FIG. 3 is a flowchart of a process for self-calibration by a DSP according to the present invention. In FIG. 3, steps 310 and 318 correspond to steps for calibrating the DC offset characteristics of the RX side, steps 320 and 328 correspond to steps for calibrating the imbalance characteristics of the RX side, and steps 330 and 332 correspond to steps for calibrating the imbalance characteristics of the TX side.

Referring to FIG. 3, in step 310 the DSP 210 applies a baseband test signal I_{TX#1} to the I channel path of the TX side in order to calibrate the DC offset of the RX side. However, no separate test signal is applied to the Q channel path.

In step 312, the DSP 210 receives the test signals I_{RX#1} and Q_{RX#1} through the I channel path and the Q channel path of the RX side, respectively. The test signals I_{RX#1} and Q_{RX#1} received from the RX side originate from the test signal I_{TX#1} applied to the TX side.

In step 314 the DSP 210 applies a baseband test signal I_{TX#2} to the I channel path of the TX side in order to calibrate the DC offset of the RX side. In this step also, no separate test signal is applied to the Q channel path.

In step 316, the DSP 210 receives the test signals I_{RX#2} and Q_{RX#2} through the I channel path and the Q channel path of the RX side, respectively. The test signals I_{RX#2} and Q_{RX#2} received from the RX side originate from the test signal I_{TX#2} applied to the TX side.

In step 318, the DSP 210 estimates and calibrates the DC offset characteristics of the RX side. Specifically, the DSP 210 estimates the DC offset characteristics of the I channel path and the Q channel path of the RX side by using the received test signals I_{RX#1}, Q_{RX#1}, I_{RX#2}, and Q_{RX#2}. The DC offset characteristics of the I channel path and the Q channel path of the RX side can be estimated by using Equation (12) described above. Then, the DSP 210 determines DC offset calibration values for calibrating the estimated DC offset characteristics of the I channel path and the Q channel path of the RX side.

The DSP converts the determined DC offset calibration values to analog signals and provides the analog signals to the I channel path and the Q channel path of the RX side, thereby calibrating the DC offset characteristics for the I channel reception signal and the Q channel reception signal.

The above discussion is based on an assumption that the DSP applies the second test signal I_{TX#2} after receiving a signal corresponding to the first test signal I_{TX#1}. However, it is also possible to sequentially apply the first and second test signals and then sequentially receive signals corresponding to the test signals.

In step 320, the DSP 210 applies a baseband test signal I_{TX#1} to the I channel path of the TX side in order to calibrate the imbalance characteristics of the RX side. No separate test signal is applied to the Q channel path.

In step 322, the DSP 210 receives the test signals I_{RX#1} and Q_{RX#1} through the I channel path and the Q channel path of the RX side, respectively. The test signals I_{RX#1} and Q_{RX#1} received from the RX side originate from the test signal I_{TX#1} applied to the TX side.

In step 324 the DSP 210 applies a baseband test signal I_{TX#3} to the I channel path of the TX side in order to calibrate the imbalance characteristics of the RX side (step 324). In this step also, no separate test signal is applied to the Q channel path.

In step 326, the DSP 210 receives the test signals I_{RX#3} and Q_{RX#3} through the I channel path and the Q channel path of the RX side, respectively. The test signals I_{RX#3} and Q_{RX#3} received from the RX side originate from the test signal I_{TX#3} applied to the TX side.

In step 328, the DSP 210 estimates the gain imbalance characteristics α2 and the phase imbalance characteristics φ2 by using the received test signals I_{RX#1}, Q_{RX#1}, I_{RX#3}, and Q_{RX#3}. The gain imbalance characteristics α2 and the phase imbalance characteristics φ2 can be estimated by using Equation (18) defined above.

The DSP 210 determines calibration values K and L for calibrating the estimated imbalance characteristics between the I channel path and the Q channel path of the RX side by using the gain imbalance characteristics α2 and the phase imbalance characteristics φ2. The calibration values K and L can be estimated by using Equation (20) defined above.

The DSP calibrates the imbalance characteristics between the I channel reception signal and the Q channel reception signal by using the calibration values K and L. The calibration of the imbalance characteristics can be achieved by outputting a new Q channel reception signal, which is obtained by adding the I channel reception signal multiplied by K and the Q channel reception signal multiplied by L.

The above discussion is based on an assumption that the DSP applies the second test signal I_{TX#3} after receiving a signal corresponding to the first test signal I_{TX#1}. However, it is also possible to sequentially apply the first and second test signals and then sequentially receive signals corresponding the test signals.

In step 330, the DSP 210 applies test signals I_{TX} and Q_{TX} for calibrating the imbalance characteristics of the TX side to the TX side. The test signals are applied to the I channel path or the Q channel path, respectively. It is assumed that the test signal I_{TX} has a value of 0 and the test signal Q_{TX} has a value of 1. No signal is applied to the I channel path of the TX side at all.

In step 332, the DSP 210 applies test signals I_{RX} and Q_{RX} from the RX side. The test signals I_{RX} and Q_{RX} received through the I channel path and the Q channel path of the RX side originate from the test signals I_{TX} and Q_{TX} applied to the TX side.

In step 334, the DSP 210 estimates and calibrates the gain imbalance characteristics of the TX side. Specifically, the DSP 210 estimates the gain imbalance characteristic axl and the phase imbalance characteristic φ1 by using the received test signals I_{RX} and Q_{RX} The gain imbalance characteristic cal and the phase imbalance characteristic φ1 can be estimated by using Equation (23) defined above.

The DSP 210 calculates the calibration values M and N for calibrating the imbalance characteristics between the I channel path and the Q channel path of the TX side by using the gain imbalance characteristic α1 and the phase imbalance characteristic φ1. The calibration values M and N can be calculated by using Equation (11) defined above.

The DSP 210 calibrates the imbalance characteristics between the I channel transmission signal and the Q channel transmission signal by using the calibration values M and N. The calibration of the imbalance characteristics can be achieved by outputting a new I channel transmission signal obtained by adding the I channel transmission signal and the Q channel transmission signal multiplied by M, and by outputting a new Q channel transmission signal obtained by multiplying the Q channel transmission signal by N.

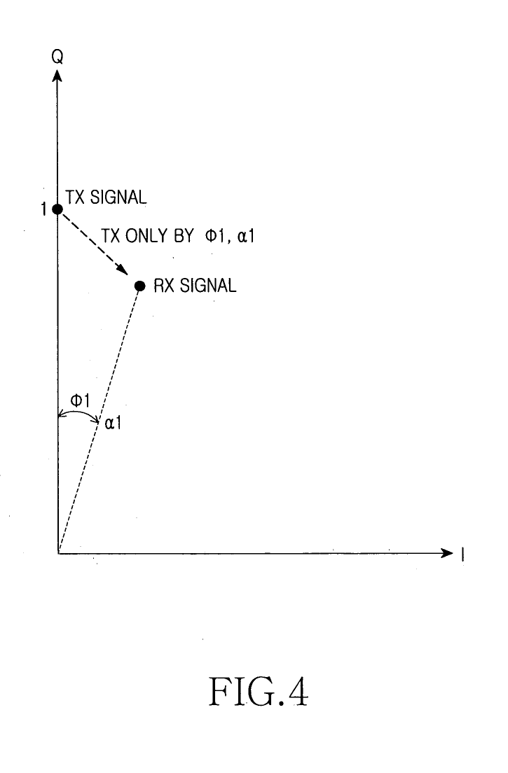

FIG. 4 is a graph for illustrating a comparison between a test signal (TX signal) transmitted to the TX side and a test signal (RX signal) received from the RX side. FIG. 4 is based on an assumption that the DC offset characteristic and the imbalance characteristic of the RX side have been already calibrated.

As noted from FIG. 4, the TX signal and the RX signal coincide with each other due to α1 and φ1 caused by the imbalance characteristics of the TX side. Therefore, the present invention has proposed a solution for estimating and then compensating α1 and φ1. By calibrating the imbalance characteristics of the TX side as described above, it is possible to make the TX signal and the RX signal coincide with each other.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A method for self-calibration in a transceiver having a test path for applying a Radio Frequency (RF) band signal from a transmission side to a reception side, the method comprising the steps of:
sequentially generating a first in-phase channel test signal and a second in-phase channel test signal in an analog baseband of a transmission side at a predetermined time interval;
converting the first in-phase channel test signal and the second in-phase channel test signal of the analog baseband to a first RF band signal and a second RF band signal according to an order in which the first in-phase channel test signal and the second in-phase channel test signal are generated, and applying the first RF band signal and the second RF band signal to the reception side through the test path;
outputting first and second in-phase channel test signals and first and second quadrature-phase channel test signals by converting the first RF band signal and the second RF band signal to analog baseband signals by means of a first carrier for an in-phase channel and a second carrier for a quadrature-phase channel, respectively;
calibrating a DC offset characteristic for in-phase channel reception signals in the analog baseband of the reception side by using an average value of the first and second in-phase channel test signals; and
calibrating a DC offset characteristic for quardrature-phase channel reception signals in the analog baseband of the reception side by using an average value of the first and second quardrature-phase channel test signals.

2. The method as claimed in claim 1, wherein the first in-phase channel test signal and the second in-phase channel test signal have a phase difference of 180 degrees.

3. The method as claimed in claim 2, wherein the first in-phase channel test signal is defined by cos ω̅₀t and the second in-phase channel test signal is defined by −cos ω̅₀t.

4. The method as claimed in claim 1, further comprising:
receiving the first RF band signal converted from the first in-phase channel test signal, converting the first RF band signal to an analog baseband signal, and generating a third in-phase channel test signal in an analog baseband of a transmission side;
converting the third in-phase channel test signal to a third RF band signal and a fourth RF band signal according to a generated order and then applying the third RF band signal and the fourth RF band signal to the reception side through the test path;
outputting a third in-phase channel test signal and a third quadrature-phase channel test signal by converting the third RF band signal and the fourth RF band signal to analog baseband signals by means of the first carrier and the second carrier, respectively;
estimating a gain imbalance value α2 and a phase imbalance value φ2 of the reception side by using the third in-phase channel test signal and the third quadrature-phase channel test signal;
determining calibration values K and L based on the gain imbalance value α2 and the phase imbalance value φ2; and
calibrating an imbalance characteristic between an in-phase channel signal and a quadrature-phase channel signal in a digital baseband of the reception side by using the calibration values K and L.

5. The method as claimed in claim 1, further comprising:
sequentially generating a third in-phase channel test signal and a fourth in-phase channel test signal in an analog baseband of a transmission side at a predetermined time interval;
converting the third in-phase channel test signal and the fourth in-phase channel test signal of the analog baseband to a third RF band signal and a fourth RF band signal according to an order in which the third in-phase channel test signal and the fourth in-phase channel test signal are generated, and then applying the third RF band signal and the fourth RF band signal to the reception side through the test path;
outputting third and fourth in-phase channel test signals and third and fourth quadrature-phase channel test signals by converting the third RF band signal and the fourth RF band signal to analog baseband signals by means of the first carrier and the second carrier, respectively;
estimating a gain imbalance value α2 and a phase imbalance value φ2 of the reception side by using the third and fourth in-phase channel test signals and the third and fourth quadrature-phase channel test signals;
determining calibration values K and L based on the gain imbalance value α2 and the phase imbalance value φ2; and
calibrating an imbalance characteristic between an in-phase channel signal and a quadrature-phase channel signal in a digital baseband of the reception side by using the calibration values K and L.

6. The method as claimed in claim 4, wherein the gain imbalance value α2 is estimated by
$$α2 = \sqrt{\frac{u {2}^{2} + u {4}^{2}}{u {1}^{2} + u {3}^{2}}} ,$$
where u1 has a value of
$$- \frac{α2 \cdot A}{2} sin ( θ - ϕ2 ) ,$$
u2 has a value of
$$\frac{A}{2} cos θ ,$$
u3 has a value of
$$\frac{A}{2} sin θ ,$$
and u4 has a value of
$$\frac{α2 \cdot A}{2} cos ( θ - ϕ2 ) .$$

7. The method as claimed in claim 4, wherein the gain imbalance value φ2 is estimated by
$$ϕ2 = {tan}^{- 1} ( \frac{2 \cdot u 1 \cdot u 3}{u {1}^{2} - u {3}^{2}} ) .$$
where u1 has a value of
$$\frac{A}{2} cos θ ,$$
u2 has a value of
$$\frac{A}{2} sin θ ,$$
u3 has a value of
$$- \frac{α 2 \cdot A}{2} sin ( θ - ϕ 2 ) ,$$
and u4 has a value of
$$\frac{α 2 \cdot A}{2} cos ( θ - ϕ 2 ) .$$

8. The method as claimed in claim 7, wherein the calibration values K and L are calculated by
$$K = - tan ϕ2$$
$$L = \frac{1}{α 2 cos ϕ 2} .$$

9. The method as claimed in claim 4, wherein the third in-phase channel test signal and the fourth in-phase channel test signal have a phase difference of 90 degrees.

10. The method as claimed in claim 7, wherein the third in-phase channel test signal is defined by cos ω̅₀t and the fourth in-phase channel test signal is defined by sin ω̅₀t.

11. The method as claimed in claim 4, further comprising:
generating a fifth quadrature-phase channel test signal in an analog baseband of a transmission side;
converting the fifth quadrature-phase channel test signal to an RF band signal and then applying the RF band signal to the reception side through the test path;
outputting a fifth in-phase channel test signal lTX and a fifth quadrature-phase channel test signal Q_{TX} by converting the RF band signal to analog baseband signals by means of the first carrier and the second carrier, respectively;
estimating a gain imbalance valueα1 and a phase imbalance value φ1 of the transmission side by using the fifth in-phase channel test signal I_{TX} and the fifth quadrature-phase channel test signal Q_{TX}; and
determining calibration values M and N based on the gain imbalance value α1 and the phase imbalance value φ1; and
calibrating an imbalance characteristic between an in-phase channel signal and a quadrature-phase channel signal in a digital baseband of the transmission side by using the calibration values M and N.

12. The method as claimed in claim 11, wherein the gain imbalance value α1 is estimated by
α1=\sqrt{I_{RX}²+Q_{RX}²}.
where Irx is the in-phase channel test signal and Qrx is the quadrature-phase channel test signal.

13. The method as claimed in claim 12, wherein the phase imbalance φ1 is estimated by
$$ϕ 1 = {tan}^{- 1} \frac{{I}_{RX}}{{Q}_{RX}} .$$

14. The method as claimed in claim 13, wherein the calibration values M and N are calculated by
$$M = - tan ϕ 1$$
$$N = \frac{1}{α 1 cos ϕ 1} .$$

15. The method as claimed in claim 14, wherein the fifth quadrature-phase channel test signal has a value of 1.

16. An apparatus for self-calibration in a transceiver having a test path for applying a Radio Frequency (RF) band signal from a transmission side to a reception side, comprising:
a processor for sequentially generating a first in-phase channel test signal and a second in-phase channel test signal in an analog baseband of a transmission side at a predetermined time interval;
a converter for converting the first in-phase channel test signal and the second in-phase channel test signal of the analog baseband to a first RF band signal and a second RF band signal according to an order in which the first in-phase channel test signal and the second in-phase channel test signal are generated, and then applying the first RF band signal and the second RF band signal to the reception side through the test path;
a mixer for first and second outputting first and second in-phase channel test signals and first and second quadrature-phase channel test signals by converting the first RF band signal and the second RF band signal to analog baseband signals by means of a first carrier for an in-phase channel and a second carrier for a quadrature-phase channel, respectively;
the processor for calibrating a DC offset characteristic for in-phase channel reception signals in the analog baseband of the reception side by using an average value of the first and second in-phase channel test signals; and
the processor for calibrating a DC offset characteristic for quardrature-phase channel reception signals in the analog baseband of the reception side by using an average value of the first and second quardrature-phase channel test signals.

17. The apparatus as claimed in claim 16, wherein the first in-phase channel test signal and the second in-phase channel test signal have a phase difference of 180 degrees.

18. The apparatus as claimed in claim 17, wherein the first in-phase channel test signal is defined by cos ω̅₀t and the second in-phase channel test signal is defined by −cos ω̅₀t.

19. The apparatus as claimed in claim 16, wherein the apparatus sequentially generates a third in-phase channel test signal and a fourth in-phase channel test signal in an analog baseband of a transmission side at a predetermined time interval;
converts the third in-phase channel test signal and the fourth in-phase channel test signal of the analog baseband to a third RF band signal and a fourth RF band signal according to an order in which the third in-phase channel test signal and the fourth in-phase channel test signal are generated, and applies the third RF band signal and the fourth RF band signal to the reception side through the test path;
outputs third and fourth in-phase channel test signals and third and fourth quadrature-phase channel test signals by converting the third RF band signal and the fourth RF band signal to analog baseband signals by means of the first carrier and the second carrier, respectively;
estimates a gain imbalance value α2 and a phase imbalance value φ2 of the reception side by using the third and fourth in-phase channel test signals and the third and fourth quadrature-phase channel test signals;
determines calibration values K and L based on the gain imbalance value α2 and the phase imbalance value φ2;
calibrates an imbalance characteristic between an in-phase channel signal and a quadrature-phase channel signal in a digital baseband of the reception side by using the calibration values K and L.

20. The apparatus as claimed in claim 16, wherein the apparatus receives the first RF band signal converted from the first in-phase channel test signal, converts the first RF band signal to an analog baseband signal, and generates a third in-phase channel test signal in an analog baseband of a transmission side;
converts the third in-phase channel test signal to a third RF band signal and a fourth RF band signal according to a generated order and applies the third RF band signal and the fourth RF band signal to the reception side through the test path;
outputs a third in-phase channel test signal and a third quadrature-phase channel test signal by converting the third RF band signal and the fourth RF band signal to analog baseband signals by means of the first carrier and the second carrier, respectively;
estimates a gain imbalance value α2 and a phase imbalance value φ2 of the reception side by using the third in-phase channel test signal and the third quadrature-phase channel test signal;
determines calibration values K and L based on the gain imbalance value α2 and the phase imbalance value φ2; and
calibrates an imbalance characteristic between an in-phase channel signal and a quadrature-phase channel signal in a digital baseband of the reception side by using the calibration values K and L.

21. The apparatus as claimed in claim 19, wherein the gain imbalance value α2 is estimated by
$$α 2 = \sqrt{\frac{u {2}^{2} + u {4}^{2}}{u {1}^{2} + u {3}^{2}}} ,$$
where u1 has a value of
$$\frac{A}{2} cos θ , u 2$$
has a value of
$$- \frac{α 2 \cdot A}{2} sin ( θ - ϕ 2 ) ,$$
u3 has a value of
$$\frac{A}{2} sin θ ,$$
and u4 has a value of
$$\frac{α 2 \cdot A}{2} cos ( θ - ϕ 2 ) .$$

22. The apparatus as claimed in claim 21, wherein the gain imbalance value Ø2 is estimated by
$$ϕ 2 = {tan}^{- 1} ( \frac{2 \cdot u 1 \cdot u 3}{u {1}^{2} - u {3}^{2}} ) .$$

23. The apparatus as claimed in claim 22, wherein the calibration values K and L are calculated by
$$K = - tan ϕ 2$$
$$L = \frac{1}{α 2 cos ϕ 2} .$$

24. The apparatus as claimed in claim 19, wherein the third in-phase channel test signal and the fourth in-phase channel test signal have a phase difference of 90 degrees.

25. The apparatus as claimed in claim 24, wherein the third in-phase channel test signal is defined by cos ω̅₀t and the fourth in-phase channel test signal is defined by sin ω̅₀t.

26. The apparatus as claimed in claim 19, wherein the apparatus generates a fifth quadrature-phase channel test signal in an analog baseband of a transmission side;
converts the fifth quadrature-phase channel test signal to an RF band signal and then applying the RF band signal to the reception side through the test path;
outputs a fifth in-phase channel test signal I_{TX} and a fifth quadrature-phase channel test signal Q_{TX} by converting the RF band signal to analog baseband signals by means of the first carrier and the second carrier, respectively;
estimates a gain imbalance value α1 and a phase imbalance value φ1 of the transmission side by using the fifth in-phase channel test signal I_{TX} and the fifth quadrature-phase channel test signal Q_{TX};
determines calibration values M and N based on the gain imbalance value α1 and the phase imbalance value φ1; and
calibrates an imbalance characteristic between an in-phase channel signal and a quadrature-phase channel signal in a digital baseband of the transmission side by using the calibration values M and N.

27. The apparatus as claimed in claim 26, wherein the gain imbalance value α1 is estimated by
α1=\sqrt{I_{RX}²+Q_{RX}²}.
where Irx is the in-phase channel test signal and Qrx is the quadrature-phase channel test signal.

28. The apparatus as claimed in claim 27, wherein the phase imbalance φ1 is estimated by
$$ϕ 1 = {tan}^{- 1} \frac{{I}_{RX}}{{Q}_{RX}} .$$

29. The apparatus as claimed in claim 28, wherein the calibration values M and N are calculated by
$$M = - tan ϕ 1$$
$$N = \frac{1}{α 1 cos ϕ 1} .$$

30. The apparatus as claimed in claim 29, wherein the fifth quadrature-phase channel test signal has a value of 1.
